(19) United States
(12) Patent Application Publication
(10) Pub. No.: US 2025/0127065 A1
(43) Pub. Date: Apr. 17, 2025

(54) SUPERCONDUCTING LAYER THIN FILM DEPOSITION DEVICE BY PULSED LASER DEPOSITION

(71) Applicant: MARU L&C Co., Ltd., Daegu (KR)

(72) Inventors: Dong Jin KIM, Daegu (KR); Man Ho CHOI, Daegu (KR)

(21) Appl. No.: 18/941,422

(22) Filed: Nov. 8, 2024

Related U.S. Application Data
(63) Continuation of application No. PCT/KR2024/008150, filed on Jun. 13, 2024.

(30) Foreign Application Priority Data
Oct. 11, 2023 (KR) 10-2023-0134751

(51) Int. Cl. H10N 60/01; C23C 14/34

(52) U.S. Cl. CPC H10N 60/01; C23C 14/3485

(57) ABSTRACT

A device for preventing contamination of a chamber window is provided, which enables a PLD process to be performed for a long period of time without replacing the chamber window, by improving an existing technology, in which a deposition material is deposited on the chamber window, and thus, a process has to be stopped, and the maintenance has to be performed, in a pulsed laser deposition (PLD), which irradiates a thin film with pulsed laser to deposit the generated plume on a substrate.

### CROSS-REFERENCE TO RELATED APPLICATION

This application is a continuation application of International Patent Application No. PCT/KR2024/008150, filed on Jun. 13, 2024, which claims priority to Korean Patent Application No. 10-2023-0134751 filed on Oct. 11, 2023 and all the benefits accruing therefrom under 35 U.S.C. § 119, the contents of which are incorporated by reference in their entirety.

### BACKGROUND

The present invention relates to a superconducting layer thin film deposition device using a pulsed laser deposition PLD technology.

Generally, due to miniaturization and high integration of electronic and electrical devices, elements used in each device are also becoming miniaturized and highly integrated.

To achieve the miniaturization and high integration of elements, oxide thin film elements such as superconductors and semiconductors are widely used, and it is most important to form the thin films thinly, widely, and evenly.

To form superconductors, semiconductors, or oxide thin films, sputtering deposition methods or pulsed laser deposition methods are being studied.

The deposition methods complete elements by depositing a superconducting thin film on an upper portion of a predetermined substrate or by depositing an electrode on an upper portion of a predetermined substrate and depositing a dielectric thin film on an upper portion of the electrode, and then depositing an electrode on an upper portion of the dielectric thin film.

The pulsed laser deposition device places a target at a position facing the substrate within a vacuum chamber and then focuses pulsed laser beam onto the target to irradiate the laser beam so that the high-temperature target generates an atomic gas.

The atomic gas reaches the substrate from the target in the form of a plume having a predetermined shape.

Atoms that reach the substrate may form a thin film having a predetermined thickness and the same composition as the target material that maintains a minimum binding energy state through a chemical reaction and a reaction with the substrate atoms on a substrate surface.

The pulsed laser deposition device may operate multiple targets and may manufacture various types of thin films in a chamber while maintaining a vacuum state, and thus, the pulsed laser deposition device may have an advantage of being able to grow high-quality thin films with a desired composition ratio without impurities or defects.

Thin film deposition variables of the pulsed laser deposition device may include a substrate temperature, a deposition gas type, a gas partial pressure, laser energy, and a distance between the target and the substrate. The deposition variables may be slightly changed for each experiment to affect reproducibility of the experiment, and thus, it is important to maintain the same deposition conditions.

In the related art, since pulsed laser is irradiated a plate-shaped target to allow an atomic gas to be ejected from the target, the laser may be focused only on a specific portion of the target, and thus, there is a limitation of increasing cost because the target has to be replaced only when a specific portion of the target is consumed, and there is a limitation of decreasing in work efficiency due to work stoppage caused by the target replacement.

### PRIOR ART DOCUMENTS

### Patent Documents

(Patent Document 1) Korean Patent Application No. 10-2006-0032939.

### SUMMARY

The present invention provides a superconducting layer thin film deposition device by pulsed laser deposition, which transforms an existing disc or plate-shaped target into a cylindrical target to uniformly form a plume, and thus, plume particles are deposited on a substrate to form a high-quality thin film so that lifespan of the target is extended to maintain work continuity, and a target holder is cooled to prevent overheating of the target, thereby significantly improving work efficiency.

In an embodiment, a superconducting layer thin film deposition device by pulsed laser deposition, the deposition device for performing the pulsed laser deposition including: a vacuum chamber having a space therein and maintained in a vacuum state; a first laser generator and a second laser generator, which are mounted in the vacuum chamber to irradiate pulsed laser on a target; a cylindrical target including a first area to which first laser generated from the first laser generator reaches and a second area to which second laser generated from the second laser generator reaches and having a hollow; a target holder provided to be inserted into the hollow defined in the cylindrical target so as to hold the cylindrical target and including an insertion part provided with a cooling passage; a cooling device configured to circulate a cooling fluid passing through the cooling passage and emit heat of the cooling fluid; and a substrate holder configured to hold the substrate on which plum particles formed by the laser irradiated on the cylindrical target are deposited.

The cooling passage may be provided to extend in a spiral shape along an extension direction of the insertion part, and the cooling passage may be provided with a plurality of vanes arranged in a spiral shape on an inner circumferential surface to generate a vortex in flow of the cooling water.

The superconducting layer thin film deposition device may further include a target holder moving part configured to move the target holder, wherein the target holder moving part may include: a linear driving part connected to one end of the target holder, provided outside the vacuum chamber, and configured to linearly move the target holder by a predetermined length; a rotary driving part connected to one end of the target holder, provided outside the vacuum chamber, and configured to linearly move the target holder by a predetermined length; and a control part configured to adjust the linear movement distance of the linear driving part so as to set a linear position of the target or set a rotation angle of the rotary driving part.

The cooling device may be provided with an inlet at one end of the target holder, which communicates with one end of the cooling passage, and an outlet that communicates with the other end of the cooling passage, and may include a cooling water supply part that is connected to the inlet to supply cooling water, and a cooling water collection part that is connected to the outlet to collect the cooling water.

The substrate holder may include a substrate transfer part configured to move the substrate, wherein the substrate transfer part may include: an unwinding reel, from which the substrate is unwound, and a winding reel into which the substrate is wound, wherein the unwinding reel and the winding reel are respectively disposed at both sides of the outside of the vacuum chamber; a driving device configured to drive the unwinding reel and the winding reel; and a plurality of rolls which are provided inside the vacuum chamber and on which the substrate is wound to move.

The superconducting layer thin film deposition device may further include a substrate holder transfer part configured to move the substrate holder, wherein the substrate holder transfer part may include: a positioning driving part which comprises brackets mounted on an inner wall of the vacuum chamber and spaced apart from each other at both sides, both rollers axially coupled to both the brackets, a conveyor belt configured to connect the rollers at both sides, and a motor configured to transmit rotational power to the roller at one side; a connection part which is connected to the conveyor belt and to which the substrate holder is fixed, wherein the substrate holder may include first and second support members spaced apart at both sides to support both ends of the substrate, and a horizontal bar which is connected horizontally to an upper portion of each of the first and second support members and to which the connection member is mounted.

The moving unit may include: a rail part, in which a moving groove is defined in a lower portion by being cut in a longitudinal direction, a protrusion is disposed on each of both sides of the moving groove, and a space is defined therein, and which has a predetermined length and is mounted on the vacuum chamber; a body inserted into an inner space of the rail part, having a built-in driving source, provided with a rotation axis at each of both sides, and provided with a main gear on each rotation axis; and a rack gear connected to the main gear and disposed in a longitudinal direction on the protrusion of the rail part, wherein a connection member connected to a lower portion of the body and coupled to the moving groove of the rail part may be provided, and the first and second laser generators may be coupled to the connection member.

The rotary driving part may include a main rotary gear disposed on an outer surface of a second disc of one end of the target holder, an auxiliary rotary gear gear-engaged with the main rotary gear, and a motor that rotates the auxiliary rotary gear, and may further include an angle detection part configured to measure a rotation angle of the main rotary gear and adjust a rotation angle of the second motor.

The linear driving part may be provided with a linear gear part provided in a predetermined section at one end of the target holder, and a motor to which a spur gear that is gear-coupled to the linear gear part is axially coupled.

### BRIEF DESCRIPTION OF THE DRAWINGS

Exemplary embodiments can be understood in more detail from the following description taken in conjunction with the accompanying drawings, in which:

FIG. 1 is a view of a superconducting layer thin film deposition device using pulsed laser deposition according to the present invention;

FIG. 2 is a flowchart of a superconducting layer thin film deposition device using pulsed laser deposition according to the present invention;

FIG. 3 is a perspective view of the superconducting layer thin film deposition device using the pulsed laser deposition according to the present invention;

FIG. 4 is a front view of the superconducting layer thin film deposition device using the pulsed laser deposition according to the present invention;

FIG. 5 is a perspective view of a target holder having a spiral passage in the superconducting layer thin film deposition device using the pulsed laser deposition according to the present invention;

FIG. 6 is a side view of a laser generator provided with a moving unit in the superconducting layer thin film deposition device using the pulsed laser deposition according to the present invention;

FIG. 7 is a front view of the laser generator provided with the moving unit in the superconducting layer thin film deposition device using the pulsed laser deposition according to the present invention; and

FIG. 8 is a view of a substrate holder transfer device in the superconducting layer thin film deposition device using the pulsed laser deposition according to the present invention.

### DETAILED DESCRIPTION OF EMBODIMENTS

Hereinafter, embodiments will be described in detail with reference to the accompanying drawings. However, various changes may be made to the embodiments, so the scope of rights of the patent application is not restricted or limited by these embodiments. It should be understood that all changes, equivalents, or substitutes for the embodiments are included in the scope of rights.

Specific structural or functional descriptions of the embodiments are disclosed for illustrative purposes only and may be modified and implemented in various forms. Thus, the embodiments are not limited to the specific disclosed form, and the scope of the present specification includes changes, equivalents, or substitutes included in the technical spirit.

The terms such as first or second may be used to describe various components, but these terms should be interpreted only for the purpose of distinguishing one component from another component. For example, a first component may be named a second component, and similarly, a second component may also be named a first component.

It will also be understood that when an element is referred to as being ‘connected to’ another element, it can be directly connected to the other element, or intervening elements may also be present.

The terms used in the embodiments are for descriptive purposes only and should not be construed as limiting. The terms of a singular form may include plural forms unless referred to the contrary. In this specification, it should be understood that the terms such as “comprise/include” or “have” are intended to designate the presence of features, numbers, steps, operations, components, parts, or combinations thereof described in the specification, but does not exclude in advance the possibility of the existence or addition of elements, numbers, steps, operations, components, parts, or combinations thereof.

Unless otherwise defined, all terms used herein, including technical or scientific terms, have the same meaning as generally understood by a person of ordinary skill in the technical field to which the embodiments belong. Terms such as terms that are generally used and have been in dictionaries should be construed as having meanings matched with contextual meanings in the art. In this description, unless defined clearly, terms are not ideally, excessively construed as formal meanings.

In addition, when describing with reference to the accompanying drawings, identical components will be assigned the same reference numerals regardless of the reference numerals, and overlapping descriptions thereof will be omitted. In describing the embodiments, if it is determined that detailed descriptions related to known technologies may unnecessarily obscure the gist of the embodiments, the detailed descriptions are omitted.

Advantages and features of the present disclosure, and implementation methods thereof will be clarified through following embodiments described with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Further, the present invention is only defined by scopes of claims.

In the embodiments of the present invention, unless otherwise defined, all terms used herein, including technical or scientific terms, are the same as those commonly understood by a person of ordinary skill in the technical field to which the present invention pertains. Terms defined in commonly used dictionaries should be interpreted as having meanings consistent with the meanings they have in the context of the relevant technology. In this description, unless defined clearly, terms are not ideally, excessively construed as formal meanings.

Since a shape, a ratio, an angle, a number, etc., which are shown in the accompanying drawings are exemplarily illustrated, the present disclosure is not limited thereto. Moreover, detailed descriptions related to well-known functions or configurations will be ruled out in order not to unnecessarily obscure subject matters of the present disclosure. When ‘comprising’, ‘having’, ‘consisting of’, etc. are used, other components can be added unless ‘only’ is used. Even when a component is explained in singular number they may be interpreted as plural number.

In interpretation of the components, even though separate explicit expressions are not provided, they are to be interpreted as including general tolerance.

When positional relation of two portions is explained by ‘on’, ‘upper’, ‘lower’, ‘beside’, etc., one or more components may be positioned between two portions unless ‘just’ is not used. When portions are connected by ‘or’, the portions are interpreted as including ‘alone’ as well as ‘combination thereof’ but when portions are connected by ‘or’, ‘one of’, portions are interpreted as ‘alone’.

When an element or layer is referred to as “on” another element or layer, it includes instances where the element or layer is directly on top of or intervening with another element. Like reference numerals refer to like elements throughout.

The size and thickness of each component shown in the drawings are shown for convenience of explanation, and the present invention is not necessarily limited to the size and thickness of the components shown.

Each feature of the various embodiments of the present invention can be partially or fully coupled or combined with each other, and as can be fully understood by those skilled in the art, various technical interconnections and operations are possible. Also, the embodiments may be independently performed with respect to each other or performed in combination of each other.

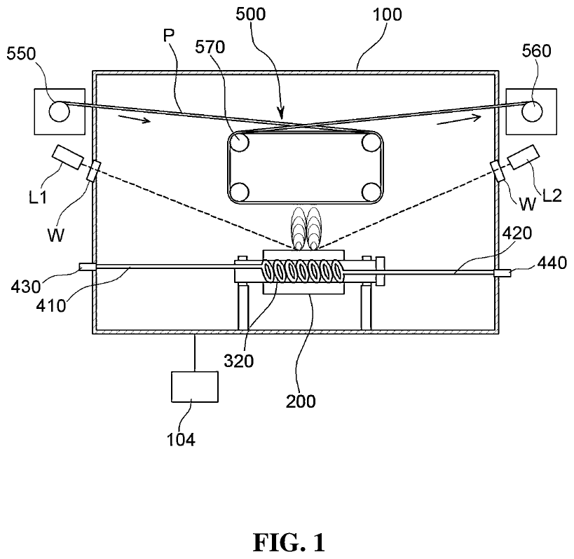

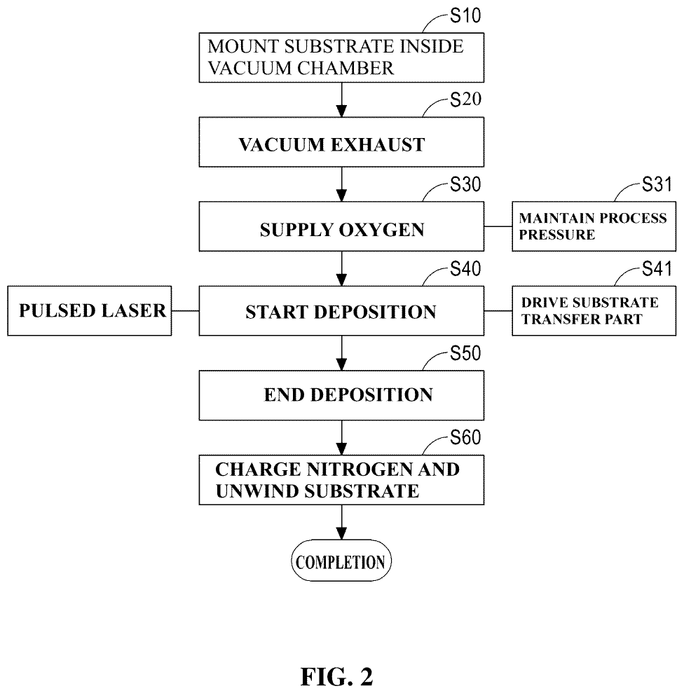

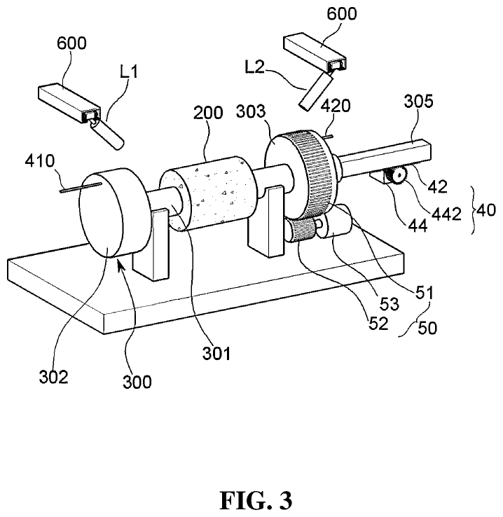

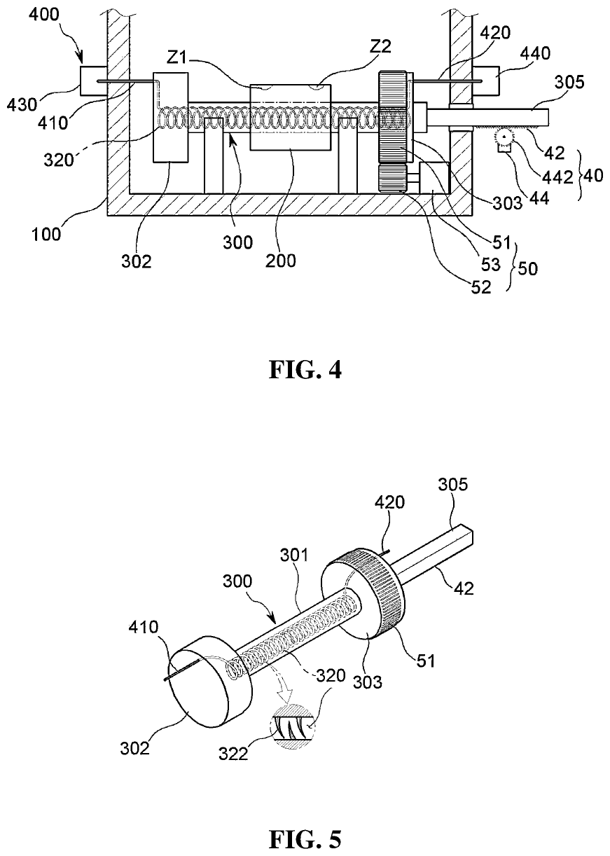

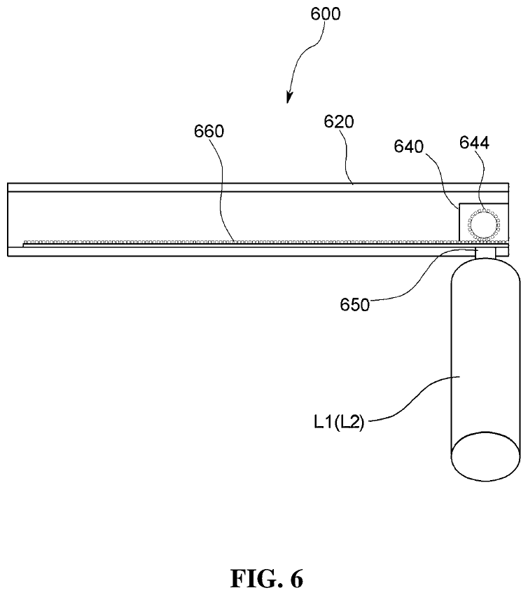

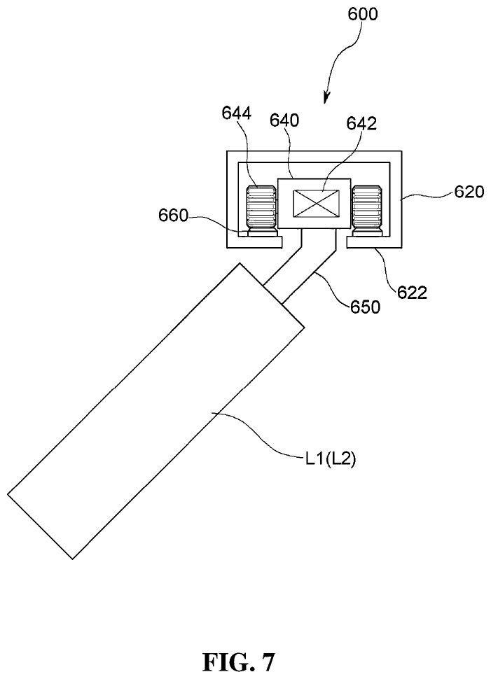

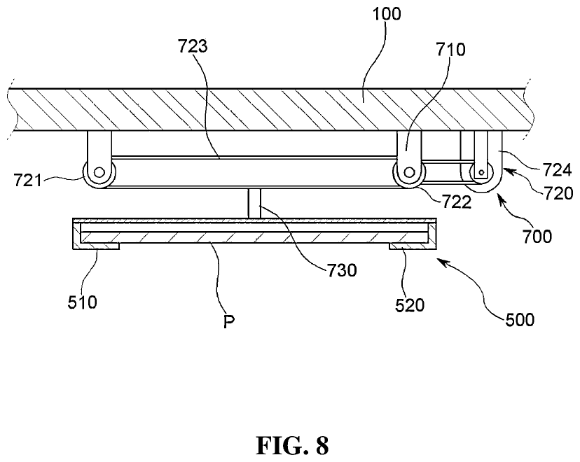

In the attached drawings, FIG. 1 is a view of a superconducting layer thin film deposition device using pulsed laser deposition according to the present invention, FIG. 2 is a flowchart of a superconducting layer thin film deposition device using pulsed laser deposition according to the present invention, FIG. 3 is a perspective view of the superconducting layer thin film deposition device using the pulsed laser deposition according to the present invention, FIG. 4 is a front view of the superconducting layer thin film deposition device using the pulsed laser deposition according to the present invention, FIG. 5 is a perspective view of a target holder having a spiral passage in the superconducting layer thin film deposition device using the pulsed laser deposition according to the present invention, FIG. 6 is a side view of a laser generator provided with a moving unit in the superconducting layer thin film deposition device using the pulsed laser deposition according to the present invention, FIG. 7 is a front view of the laser generator provided with the moving unit in the superconducting layer thin film deposition device using the pulsed laser deposition according to the present invention, and FIG. 8 is a view of a substrate holder transfer device in the superconducting layer thin film deposition device using the pulsed laser deposition according to the present invention.

A superconductor is a material that has zero electrical resistance below a critical temperature (Tc) and exhibits perfect diamagnetism, which is called an Meissner effect.

First-generation superconductivity was discovered first in 1911 when electrical resistance of mercury becomes zero a temperature of about 4.2 K in liquid helium, and second-generation superconductivity was discovered in 1986 when copper oxide superconductors were discovered.

It includes rare earth oxides represented by oxide superconductors (REBCO: RE is one or more rare earth elements (Sc, Y, La, Ce, Pr, Nd, Pm, Sm, Eu, Gd, Tb, Dy, Ho, Er, Tm, Yb, and Lu)), and as oxides, (YBa2Cu₃O₇₋ₓ), (GdBa₂Cu₃O₇₋ₓ) or, RE, Ba, Cu mean individual oxide particle substances, or two or more mean complex oxide particles among these elements.

The most important condition for using second-generation high-temperature superconductor (HTS) wires in superconducting applications is a high critical current (IC) value under high magnetic fields.

In particular, the critical current density (JC) should be as large as possible even under large magnetic fields applied in an arbitrary direction. A limit of a critical current density is determined by an action of a flux pinning center (artificial pin) that prevents magnetic flux lines distributed inside the superconductor from moving against the Lorenz force when being invade from the outside to try to move due to the Lorenz force.

Here, many researchers and inventors have developed a method to increase in critical current size under the magnetic fields by doping nano-sized non-superconducting particles into the superconducting layer.

In general, materials that constitute the magnetic flux pinning point may include at least one of BaHfO₃, SrHfO₃, CaHfO₃, BaZrO₃, BaSnO₃, etc., a solid solution thereof, or a mixture of two or more thereof.

The superconducting layer of REBCO-based high-temperature superconducting wires may be formed by various methods including pulsed laser deposition PLD, metal organic chemical vapor deposition (MOCVD), metal organic deposition (MOD), and reactive co-evaporation (RCE).

Among them, the PLD method is particularly effective in obtaining two-axis oriented thin films. The PLD method that is one of the methods for depositing superconductors is known as the most convenient and effective technique for manufacturing high-temperature superconductors (HTS). In the deposition of the oxide superconducting layer using the PLD method, it is possible to form an oxide superconducting layer having good film quality and obtain high superconducting characteristics.

The PLD method is a method of striking a solid REBCO target using laser focused from a lens and separating the target material from a surface to form plasma in the form of a gas stream (plume), thereby crystallizing the plume material on the surface of a wire heated to a high temperature.

The advantages of the PLD are that the thin film is formed with a chemical composition close to that of the target material, has low contamination, and has a high deposition rate. On the other hand, it has a disadvantage of low productivity compared to other manufacturing methods.

In order to increase in productivity in the PLD method, a method of increasing in deposition amount by irradiating the target with multiple lasers was being developed.

This patent may utilize multiple lasers and provide the device in a cylindrical shape so as to be used for a long time without replacing the target. When a plurality of lasers are irradiated simultaneously on the target, a large amount of deposition material may be generated, but at the same time, a temperature of the target rises. This is resolved by installing a cooling device.

According to the present invention, a superconducting layer thin film deposition device, to which a pulsed laser deposition (PLD) technology is applied, the deposition device for performing the pulsed laser deposition includes: a vacuum chamber 100 having a space therein and maintained in a vacuum state; a first laser generator L1 and a second laser generator L2, which are mounted in the vacuum chamber 100 to irradiate pulsed laser on a target 200; a cylindrical target 200 including a first area Z1 to which first laser generated from the first laser generator L1 reaches and a second area Z2 to which second laser generated from the second laser generator L2 reaches and having a hollow; a target holder 300 provided to be inserted into the hollow defined in the cylindrical target 200 so as to hold the cylindrical target 200 and including an insertion part 310 provided with a cooling passage 320; a cooling device 400 configured to circulate a cooling fluid passing through the cooling passage 320 and emit heat of the cooling fluid; and a substrate holder 500 configured to hold the substrate P on which plum particles formed by the laser irradiated on the cylindrical target 200 are deposited.

The vacuum chamber 100 may be connected to a vacuum pump 104 so that an internal pressure is reduced by vacuum exhaust to a pressure that is suitable for process conditions.

A deposition chamber, an unwinding chamber, and a winding chamber are connected by vacuum (not shown) and may be configured as a single chamber.

A shield plate (not shown) configured to protect the inside of the vacuum chamber 100 and a rear surface of the substrate, which is not deposited (from the deposition material) is provided in the deposition chamber.

The substrate heating unit (not shown) heats the rear surface of the substrate, on which deposition is being performed (power-on heater), to ensure that the deposition material is well deposited during the deposition.

Each of the first laser generator L1 and the second laser generator L2 may be mounted outside the vacuum chamber 100 to irradiate the pulsed laser toward the target 200 through a window W formed on a wall surface of the vacuum chamber 100 and allow an atomic gas plume emitted from the target 200 to be incident on the substrate P so that plasma particles are deposited on the substrate P.

The window W may be made of a material that is capable of transmitting laser light so that the laser generated from the first laser generator L1 or the second laser generator L2, which are disposed outside the vacuum chamber 100, are introduced into the vacuum chamber 100.

The first laser generator L1 or the second laser generator L2 may be spaced apart from each other at one side and the other side of the target 200, and thus, the first area Z1 and the second area Z2 on which the laser is irradiated may be defined outside the cylindrical target 200.

Preferably, the first laser generator L1 and the second laser generator L2 may be disposed symmetrically at both sides of the target 200.

Thus, since a length of the cylindrical target 200 is long, a plurality of laser irradiation areas, i.e., the first area Z1 and the second area Z2 may be defined on the outer surface, and thus, the plume may be formed on each area to improve deposition efficiency.

A plurality of supports 110 spaced apart from each other may be provided inside the vacuum chamber 100, and the target holder 300 may be rotatably coupled to the plurality of supports 110.

Preferably, the target holder 300 may be rotatably mounted on the plurality of supports 110 and be provided with a rod body 301 into which an insertion part 310 of the target holder 300 is fitted, and first and second discs 302 and 303 disposed at both sides of the rod body 301.

Preferably, the first and second discs 302 and 303 may be fitted into the rod body 301 to facilitate attachment and detachment and be fitted through the second disc 303 so that the rod body 301 moves forward and backward by a certain length.

A moving bar 305 provided with a linear gear part 42 of a linear driving part 40 described later may be provided to be integrated with a rear end of the rod body 301.

The substrate holder 500 may include a substrate transfer part for moving the substrate.

The substrate transfer part may include: an unwinding reel 550, from which the substrate P is unwound, and a winding reel 560 into which the substrate P is input, wherein the unwinding reel 550 and the winding reel 560 are respectively disposed at both sides of the outside of the vacuum chamber 100; a driving device (not shown) configured to drive the unwinding reel 550 and the winding reel 560; and a plurality of rolls 570 which are provided inside the vacuum chamber 100 and on which the substrate is wound to move.

The unwinding reel 550 and the winding reel 560 may be configured as separate chambers outside the vacuum chamber 100, and the substrate may be transferred by driving the unwinding reel 550 and the winding reel 560 using the driving device (not shown).

In order to transfer a long substrate, a speed of each of the unwinding reel 550 and the winding reel 560 has to be synchronized with each other.

The rolls 570 may be provided in plurality, and the substrate transferred from the unwinding reel 550 may be transferred to the winding reel 560 after repeating the process several times during the deposition.

The cylindrical target 200 configured in a cylindrical shape may have the same composition as the material of the superconducting layer and rotate around a center of the cylinder, and when the rotation is completed, the cylindrical target 200 may move horizontally in a left (right) direction and then rotate again so that the target material outside the cylinder is used uniformly to significantly improve productivity of the substrate and efficiency of the target.

An inner surface of the target may be connected to another rotating tube, and a target temperature may be prevented from rising even when used for a long time through a cooling unit (liquid, gas, etc.).

The pulsed laser may have a high energy density and thus be good to have a high output so as to obtain a vaporization amount of target.

Applicable laser types may include Ar—F (193 nm), Kr—F (248 nm), Xe—Cl (308 nm), excimer laser, YAG laser, and CO₂ laser.

An externally oscillated laser is introduced into the vacuum chamber through a laser introduction part provided on one surface of the chamber. The introduction part may be treated with anti-reflective coating to prevent a laser beam from being reflected.

An oxygen supply port may use a vacuum pump to depressurize (vacuum) the inside of the deposition chamber and inject an ionized gas from an oxygen ionization device, thereby generating an oxygen atmosphere while maintaining a pressure inside the chamber constantly by controlling the injection amount (flow control valve).

The atmospheric pressure may be adjusted during the PLD deposition so that an inclination angle and a length of the artificial pin are changed. In addition, the inclination angle and the length of the artificial pin may be adjusted according to a pulsed laser frequency of the PLD device and the atmospheric pressure inside the chamber.

When the deposition is complete, the nitrogen gas valve may introduce a nitrogen gas (dry air) into the chamber to equalize the pressure with the atmospheric pressure, and thus, the chamber may be opened to finally unload a wire.

Referring to FIG. 2, the substrate P is mounted inside the vacuum chamber 100 (S10).

Thereafter, the vacuum chamber 100 is exhausted to create a vacuum state therein (S20).

Thereafter, oxygen is supplied to the inside of the vacuum chamber 100 (S30). In addition, a process pressure is maintained.

Thereafter, the deposition starts (S40). In addition, the substrate transfer part is driven to ensure continuous movement of the substrate P.

Thereafter, the deposition is terminated (S50).

Thereafter, the inside of the vacuum chamber 100 is filled with nitrogen, and the substrate P is unloaded (S60).

Referring to FIGS. 3 and 4, a linear driving part 40 or a rotary driving part 50 is provided to implement linear or rotary motion of the target holder 300.

In addition, it includes a control part (not shown) that sets a linear position of the target 200 by adjusting a linear movement distance of the linear driving part 40 or sets a rotation angle of the rotary driving part 50.

The linear driving part 40 is connected to one end of the target holder 300 and is provided outside the vacuum chamber 100 so that the target holder 300 moves linearly to a predetermined length.

According to an example, the linear driving part 40 is provided with a linear gear part 42 provided in a predetermined section on an outer surface of the moving bar 305 disposed at one end of the rod body 301 of the target holder 300, and a first motor 44 to which a spur gear 442 that is gear-coupled to the linear gear part 42 is axially coupled.

The first motor 44 may be turned on, and thus, the spur gear 442 may rotate forward and reverse, and the moving bar 305 connected to the linear gear part 42 and the rod body 301 of the target holder 300 may move to a left and right side, thereby allowing the target holder 300 to move to the left and right side so that the length is adjustable.

Preferably, the length by which the target holder 300 is adjusted to the left and right side should be limited to a thickness of the second plate 303 to prevent an auxiliary rotary gear 52 and a main rotary gear 51 of the rotary driving part 50 described later from being separated from each other.

The rotary driving part 50 is connected to one end of the target holder 300 and is provided outside the vacuum chamber 100 to rotate the target holder 300 at a predetermined angle.

According to an embodiment, the rotary driving part 50 may include a main rotary gear 51 disposed on an outer surface of a second disc 303 of one end of the target holder 300, an auxiliary rotary gear 52 gear-engaged with the main rotary gear 51, and a second motor 53 that rotates the auxiliary rotary gear 52, and may further include an angle detection part 54 configured to measure a rotation angle of the main rotary gear 51 and adjust a rotation angle of the second motor 53. The auxiliary rotary gear 52 may rotate by the rotation of the second motor 53, and the main rotary gear 51 gear-engaged with the auxiliary rotary gear 52 may rotate to cause the rotation of the target holder 300.

Thus, the target holder 300 may move in a linear manner in the left and right direction, and the first area Z1 to which the first laser reaches and the second area Z2 to which the second laser reaches may be changed to enable the target holder 300 to be used uniformly.

In addition, the target holder 300 may rotate, and the first area Z1 and the second area Z2 may be changed similarly so that the target holder 300 is used more uniformly.

Although the drawing of this specification illustrates a single target holder 300 and one target 200 inside the vacuum chamber 100, the number of target holders 300 placed inside the vacuum chamber 100 and the number of targets 200 mounted on the target holders 300 may be provided in plurality. For example, the target holders 300 may be disposed in parallel or series for faster and more efficient deposition operations. In some cases, the plurality of substrate holders 500 and the substrates P may be provided so that the deposition is performed simultaneously on the plurality of substrates P.

According to an embodiment, the target holder 300 may include a cooling device 400 having a cooling passage defined therein through which cooling water is circulated to have a cooling function.

According to an example, the cooling device 400 is provided with an inlet 410 at one end of the target holder 300, which communicates with one end of the cooling passage 320, and an outlet 420 that communicates with the other end of the cooling passage 320.

It also includes a cooling water supply part 430 that is connected to the inlet 410 to supply cooling water, and a cooling water collection part 440 that is connected to the outlet 420 to collect the cooling water.

Each of the cooling water supply part 430 and the cooling water collection part 440 may be provided with a pump so that the supply and collection of the cooling water are continuously circulated.

Preferably, the cooling passage 320 may be provided inside the target holder 300, but may be provided in plurality to stably implement a cooling effect throughout the target holder 300.

According to an example, the cooling passage 320 may be provided in a cylindrical shape to extend in a spiral shape along an extension direction of the insertion part 310 of the target holder 300.

The cooling passage 320 may be provided with a plurality of vanes 322 arranged in a spiral shape on an inner circumferential surface.

Thus, a flow of cooling water may be maintained stably by generating a vortex in the flow of cooling water by the plurality of vanes 322 arranged in the spiral shape, thereby improving the circulation efficiency.

The first and second laser generators L1 and L2 may be fixedly provided to irradiate the laser to a specific point of the target 200 in the basic embodiment, but if necessary, the first and second laser generators L1 and L2 may be mounted on a moving unit 600 provided in the vacuum chamber 100 so that the laser irradiation point is changed.

The moving unit 600 may move the first laser generator L1 or the second laser generator L2 so that the spots reached by the first laser and the second laser are variable.

According to an example, the moving unit 600 may include: a rail part 620, in which a moving groove is defined in a lower portion by being cut in a longitudinal direction, a protrusion 622 is disposed on each of both sides of the moving groove, and a space is defined therein, and which has a predetermined length and is mounted on the vacuum chamber 100; a body 640 inserted into an inner space of the rail part 62, having a built-in driving source 642, provided with a rotation axis at each of both sides, and provided with a main gear 644 on each rotation axis 643; and a rack gear 660 connected to the main gear 644 and disposed in a longitudinal direction on the protrusion 622 of the rail part 620 and may further include a connection member 650 connected to a lower portion of the body 640 and coupled to the moving groove of the rail part 620, wherein the first and second laser generators L1 and L2 are coupled to the connection member 650.

The driving source 642 may be a motor. The driving source 642 may be driven in the forward and reverse directions, and thus, the body 640 and the first and second laser generators L1 and L2 connected thereto may move along the rail part 620 in the forward and reverse directions, thereby enabling the position setting.

A substrate holder transfer part 700 that moves the substrate holder 500 to change a position of the substrate may be further provided.

Referring to FIG. 6, the substrate holder transfer part 700 may include: a positioning driving part 720 which includes brackets 710 mounted on an inner wall of the vacuum chamber 100 and spaced apart from each other at both sides, both rollers 721 and 722 axially coupled to both the brackets 710, a conveyor belt 723 configured to connect the rollers 721 and 722 at both sides, and a third motor 724 configured to transmit rotational power to the rollers 721 and 722 at one side; a connection part 730 which is connected to the conveyor belt 723 and to which the substrate holder 500 is fixed.

The substrate holder 500 may include first and second support members 510 and 520 spaced apart at both sides to support both ends of the substrate P, and a horizontal bar 530 which is connected horizontally to an upper portion of each of the first and second support members 510 and 520 and to which the connection member 730 is mounted.

Thus, the conveyor belt 723 may rotate forward and reverse by the forward and reverse driving of the third motor 724, and thus, the substrate holder 500 connected by the connection part 730 may move to enable a change in position.

According to the present invention, the cylindrical target may be applied to uniformly form the plume on the target, and thus, the plume particles may be deposited on the substrate to form the high-quality thin film.

In addition, the cylindrical target may be applied to extend the lifespan, thereby maintaining the work continuity.

In addition, the work efficiency may be significantly improved by preventing the overheating of the target through the cooling of the target holder.

Although embodiments of the present invention have been described in more detail with reference to the accompanying drawings, the present invention is not necessarily limited to these embodiments, and various modifications may be made without departing from the technical spirit of the present invention. Thus, the embodiment of the present invention is to be considered illustrative, and not restrictive, and the technical spirit of the present invention is not limited to the foregoing embodiment. Therefore, the embodiments described above should be understood in all respects as illustrative and not restrictive. Therefore, the scope of the present disclosure is defined not by the detailed description of the invention but by the appended claims, and all differences within the scope will be construed as being included in the present disclosure.

Therefore, other implementations, other embodiments, and equivalents of the claims also fall within the scope of the following claims.

What is claimed is:

1. A superconducting layer thin film deposition device by pulsed laser deposition, the deposition device for performing the pulsed laser deposition comprising:
a vacuum chamber having a space therein and maintained in a vacuum state;
a first laser generator and a second laser generator, which are mounted in the vacuum chamber to irradiate pulsed laser on a target;
a cylindrical target comprising a first area to which first laser generated from the first laser generator reaches and a second area to which second laser generated from the second laser generator reaches and having a hollow;
a target holder provided to be inserted into the hollow defined in the cylindrical target so as to hold the cylindrical target and comprising an insertion part provided with a cooling passage;
a cooling device configured to circulate a cooling fluid passing through the cooling passage and emit heat of the cooling fluid; and
a substrate holder configured to hold the substrate on which plum particles formed by the laser irradiated on the cylindrical target are deposited.

2. The superconducting layer thin film deposition device of claim 1, wherein the cooling passage is provided to extend in a spiral shape along an extension direction of the insertion part, and
the cooling passage is provided with a plurality of vanes arranged in a spiral shape on an inner circumferential surface to generate a vortex in flow of the cooling water.

3. The superconducting layer thin film deposition device of claim 1, further comprising a target holder moving part configured to move the target holder,
wherein the target holder moving part comprises:
a linear driving part connected to one end of the target holder, provided outside the vacuum chamber, and configured to linearly move the target holder by a predetermined length;
a rotary driving part connected to one end of the target holder, provided outside the vacuum chamber, and configured to linearly move the target holder by a predetermined length; and
a control part configured to adjust the linear movement distance of the linear driving part so as to set a linear position of the target or set a rotation angle of the rotary driving part.

4. The superconducting layer thin film deposition device of claim 1, wherein the substrate holder comprises a substrate transfer part configured to move the substrate,
wherein the substrate transfer part comprises:
an unwinding reel, from which the substrate is unwound, and a winding reel into which the substrate is wound, wherein the unwinding reel and the winding reel are respectively disposed at both sides of the outside of the vacuum chamber;
a driving device configured to drive the unwinding reel and the winding reel; and
a plurality of rolls which are provided inside the vacuum chamber and on which the substrate is wound to move.

5. The superconducting layer thin film deposition device of claim 1, further comprising a substrate holder transfer part configured to move the substrate holder,
wherein the substrate holder transfer part comprises:
a positioning driving part which comprises brackets mounted on an inner wall of the vacuum chamber and spaced apart from each other at both sides, both rollers axially coupled to both the brackets, a conveyor belt configured to connect the rollers at both sides, and a motor configured to transmit rotational power to the roller at one side;
a connection part which is connected to the conveyor belt and to which the substrate holder is fixed,
wherein the substrate holder comprises first and second support members spaced apart at both sides to support both ends of the substrate, and a horizontal bar which is connected horizontally to an upper portion of each of the first and second support members and to which the connection member is mounted,
the moving unit is configured to move the first laser generator or the second laser generator so that spots reached by the first laser and the second laser are variable,
wherein the moving unit comprises:
a rail part, in which a moving groove is defined in a lower portion by being cut in a longitudinal direction, a protrusion is disposed on each of both sides of the moving groove, and a space is defined therein, and which has a predetermined length and is mounted on the vacuum chamber;
a body inserted into an inner space of the rail part, having a built-in driving source, provided with a rotation axis at each of both sides, and provided with a main gear on each rotation axis; and
a rack gear connected to the main gear and disposed in a longitudinal direction on the protrusion of the rail part,
wherein a connection member connected to a lower portion of the body and coupled to the moving groove of the rail part is provided, and
the first and second laser generators are coupled to the connection member.
